(19) United States
(12) Patent Application Publication
(10) Pub. No.: US 2023/0122860 A1
(43) Pub. Date: Apr. 20, 2023

(54) ROTATING STORAGE DRIVE BAY LATCH

(71) Applicant: Dell Products L.P., Round Rock, TX (US)

(72) Inventors: Eduardo Escamilla, Round Rock, TX (US); Chun-Yang Tseng, Taipei City (TW); Matthew B. Gilbert, Austin, TX (US); Amrita Sidhu Maguire, Cedar Park, TX (US)

(73) Assignee: Dell Products L.P., Round Rock, TX (US)

(21) Appl. No.: 17/503,275

(22) Filed: Oct. 16, 2021

(51) Int. Cl. G06F 1/18; H05K 7/14

(52) U.S. Cl. CPC G06F 1/187; H05K 7/1417; H05K 7/1489

(57) ABSTRACT

An information handling system storage device rotationally couples first and second storage drive bays to a housing and having a gap between them. The second storage drive bay rotationally couples between a stored position in planar alignment with the first storage drive bay and a raised position that provides access to storage drives in the second storage drive bay. A latch rotationally couples to the second storage drive bay and extends in a stored position into the gap. A pin and guide arrangement defines rotation of the latch relative to the storage drive bay to a raised position and then translates upward force applied to the latch to rotate the storage drive bay to a raised position.

### BACKGROUND OF THE INVENTION

### Field of the Invention

The present invention relates in general to the field of information handling system storage devices, and more particularly to an information handling system rotating storage drive bay latch.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems include specialized storage servers that include a large number of storage devices in a shared housing, such as hard disk drives (HDD) and solid-state drives (SSD) that are held in storage bays. A typical storage server or storage array will interface the storage devices with a network interface that is accessible to an enterprise or through the Internet. Centralized storage that is accessible through a network provides a convenient solution for enterprises to store and manage large amounts of data that can accumulate related to enterprise activities. Deploying storage devices to storage bays provides a scalable and maintainable storage system. For example, as storage needs increase or decrease, the available storage is readily adjusted by adding or removing storage devices of different sizes at the storage bays. In the event of a storage device failure, the failed device is simply removed and replaced with a new storage device. As an example, one commercially available storage server supports two banks of twelve HDDs in two rows of four storage bays that each accept three HDDs. A front bank is readily accessible at a front of the server and a rear bank behind the front bank is accessible by rotating the storage bays up and out of the server housing. Generally, the storage devices insert into one of the bays to couple with a connector that interfaces the storage device with a backplane and network. After the storage drive is replaced, the bay is closed and the server interacts with the storage device.

One difficulty with arranging storage devices in a storage server is ensuring adequate cooling airflow to maintain the storage devices within operating constraints. To encourage adequate airflow and also mitigate cooling fan induced HDD read/write errors associated with acoustic dynamics, a dedicated air channel is typically provided, such as with a space between the banks of storage devices. This reserved space tends to restrict end user access to the rear bay and limits insertion or inclusion of tools to aid access to the rear bay. Another difficulty is that storage devices tend to have a relatively large weight that makes a structure for raising and lowering the rear bank of storage devices difficult. Typically, the rear bay hinge includes torque elements and an ergonomic spring to hold the rear bay in a raised position while storage devices are replaced. The relatively heavy weight of the storage devices and the forces associated with torque and spring devices can result in excessive closing and opening forces when end users attempt to access the rear bank of storage devices by grabbing onto surface edges of the rear bay.

### SUMMARY OF THE INVENTION

Therefore, a need has arisen for a system and method which provides a rotating storage drive bay latch.

In accordance with the present invention, a system and method are provided which substantially reduce the disadvantages and problems associated with previous methods and systems that manage access to storage devices disposed in storage bays. A latch rotationally couples to a storage drive bay between a stored position and a raised position accessible to an end user grasp. At the raised position, a lifting force applied to the latch translates to rotate the storage bay drive upwards and out of an information handling system housing.

More specifically, an information handling system processes information with a processor and memory disposed in a housing having a first storage drive bay exposed at one end and a second storage drive bay coupled in a middle position proximate to a rear side of the first storage drive bay with a gap between the front of the second storage drive bay and the rear of the first storage drive bay. The second storage drive bay rotationally couples to the housing with a hinge coupled to the rear of the second storage drive bay to rotate between a planar stored position and a raised position that exposes storage devices disposed in the second storage drive bay, such as hard disk drives. A latch rotationally couples on each opposing side of the second storage drive bay to assist in raising the second storage drive bay to the raised position for access to the storage devices. The latch has a stored position within the gap and held in place by a cover coupled to the housing over the gap. The latch rotates relative to the second storage drive bay to a predetermined raised position and then translates lifting force applied at the latch to rotate and raise the second storage drive bay to a raised position over the housing. As an example, the latch includes a guide that engages a pin extending from the second storage drive bay into a guide formed in the latch that defines rotation of the latch relative to the second storage drive bay and translation of force applied to the latch to rotate the storage drive bay.

The present invention provides a number of important technical advantages. One example of an important technical advantage is that a storage drive bay coupled in a middle position of a housing has a lifting force applied to transition to a raised position without end user direct engagement with storage drive bay so that risk of damage to the storage drive bay and storage devices is reduced. The latch stores in a gap under a cover out of view and extends to a raised position with minimal force. In the raised position, the latch offers an exposed grasp for an end user and provides a greater rotational moment for generating rotational force to raise the storage bay drive. The end user is offered a comfortable touchpoint that can be further eased with an elastomer or plastic overmold and that avoids introductions of sweat or grease related to human touch to the storage drive bay itself. The relatively small size of the latch does not interfere with cooling airflow or consume footprint in a gap at the front of the storage drive bay. Further, the latch offers a controlled closing and securing of the storage drive bay after maintenance, prevent storage drive damage that can occur when the storage drive bay is slammed closed. Reliable latching of the storage drive bay helps to manage shock and vibration translation to the storage devices.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a server information handling system having first and second longitudinally disposed storage drive bays, including one storage drive bay with a middle position that operates in a planar configuration relative to the server information handling system housing;

FIGS. 2 and 2A depict the server information handling system having the middle storage drive bay in a raised position;

FIGS. 3 and 3A depict the server housing with the middle-place storage drive bay held in a raised position by a hinge having a counterbalance spring; and

FIGS. 4A, 4B, 4C and 4D depict operation of the latch to manage raising of the storage bay drive to access to storage devices.

### DETAILED DESCRIPTION

An information handling system server with end-to-end placed storage drive bays raises a middle-placed storage drive bay with a latch that extends into a gap past the front of the storage drive bay in stored position and rotates up to a raised position at which the latch translates upward force into rotation of the storage drive bay. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

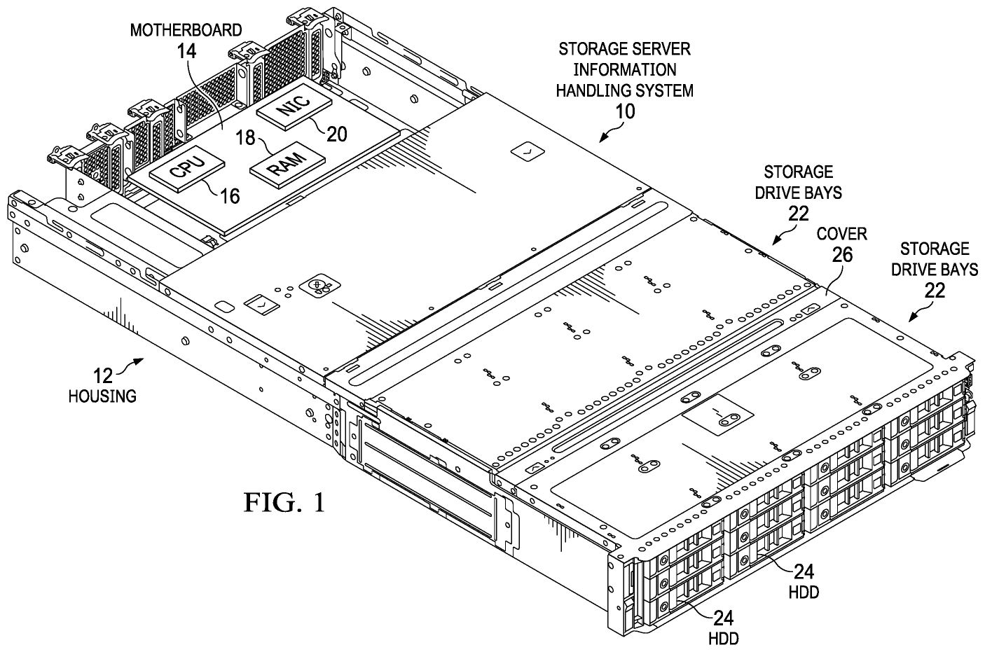

Referring now to FIG. 1, a server information handling system 10 is depicted having first and second longitudinally disposed storage drive bays 22, including one storage drive bay 22 with a middle position that operates in a planar configuration relative to the server information handling system housing 12. In the example embodiment, server information handling system 10 provides storage as a network resource with processing components disposed in a housing 12 having a planar configuration size to fit in a universal server rack. For example, housing 12 is a server rack tray configured to slide in and out of a server rack with rails and having a universal height dimension. At a rear side of housing 12 a motherboard 14 couples to housing 12 to support communication between processing components that cooperate to process information. A central processing unit (CPU) 16 executes instructions that process information in cooperation with a random access memory (RAM) 18 that stores the instructions and information. A network interface card (NIC) 20 supports network communications, such as through Ethernet cables. Although the example embodiment depicts a server configuration to support network storage, alternative embodiments may have alternative configurations to address network storage needs, such as network attached storage configuration or a storage area network configuration.

To support network storage, housing 12 has first and second longitudinally placed storage drive bays 22 that each accept plural storage devices 24, such as hard disk drives (HDD) and solid-state drives (SSD). The front place storage drive bay 22 has a fixed orientation in housing 12 that exposes storage devices 24 at the front of the information handling system when installed in a server rack. The front position of the storage drive bay 22 allows an end user to access storage devices 24, such as for replacement or maintenance. The middle-placed storage drive bay 22 has a front face at a rear side of the front placed storage drive bay 22 with a gap defined between the two storage drive bays to provide for cooling airflow through housing 12. A cover 26 is coupled to housing 12 over the gap between storage drive bays 22. In order to minimize the longitudinal length of the storage drive bays 22 in housing 12, the gap under cover 26 is minimized to that needed for airflow and the middle-positioned storage drive bay 22 is built to selectively expose the storage devices 24 in the middle-placed storage drive bay 22 by raising the front face of the middle-placed storage drive bay. In the example embodiment described in greater depth below, the middle-positioned storage bay drive 22 rotates about an axis at a rear upper side to expose storage devices 24 at a front face.

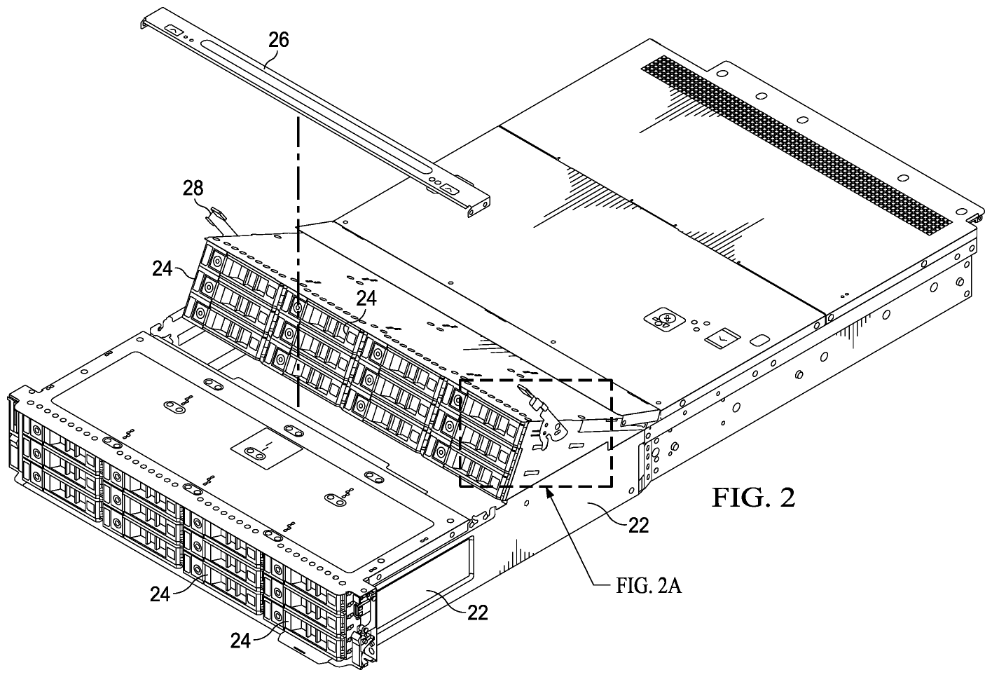

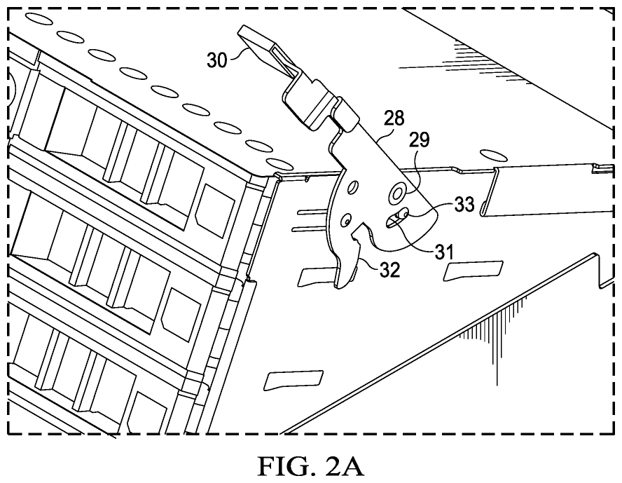

Referring now to FIGS. 2 and 2A, the server information handling system is depicted having the middle storage drive bay 22 in a raised position. Storage drive bay 22 rotates about an axis at a rear side to raise the front side and expose storage devices 24. Cover 26 lifts off housing 12 to free storage drive bay 22 to rotate with the rotational movement of the front side having space relative to the rear side of the front placed storage drive bay 22 in the gap. First and second latches 28 couple at opposite sides of storage drive bay 22 to provide a grasping location for an end user to grasp and rotate storage drive bay 22 to the depicted raised position. Latches 28 are depicted in an extended and raised position that is readily accessible to an end user for a grasp and application of a lifting force that translates to rotation of storage drive bay 22. The raised position of storage drive bay 22 is performed by sliding housing 12 out of a rack to provide vertical room, then removing cover 26 to expose latches 28 in a stored position within the gap between the rear side of the front placed storage drive bay 22 and the front side of middle-placed storage drive bay 22. To achieve the stored position, latches 28 rotate relative to storage drive bay 22 over a defined range from a planar orientation in plane with and just below the upper surface of storage drive bay 22 and the depicted raised position. At the extreme rotational position of the latch defined range of rotation, the latch reaches a stop and then acts to translate force applied to the latch as rotation of storage drive bay 22.

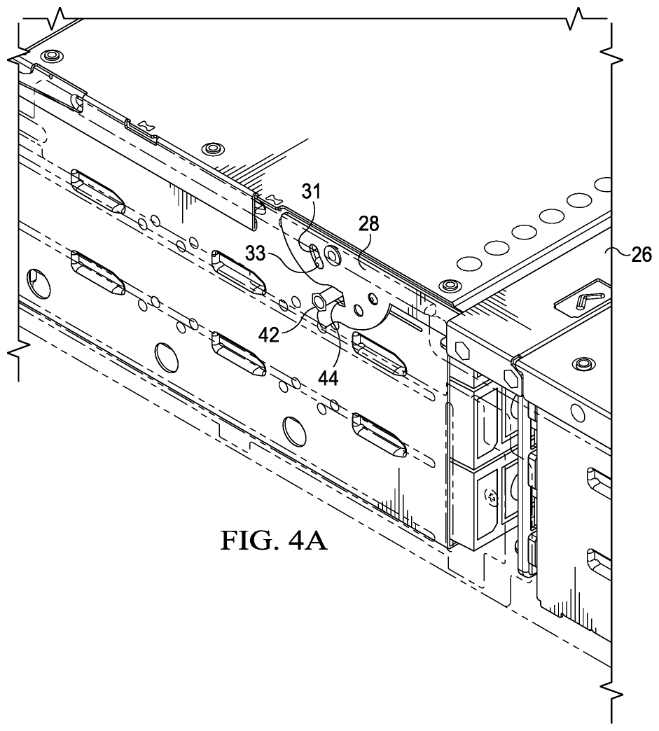

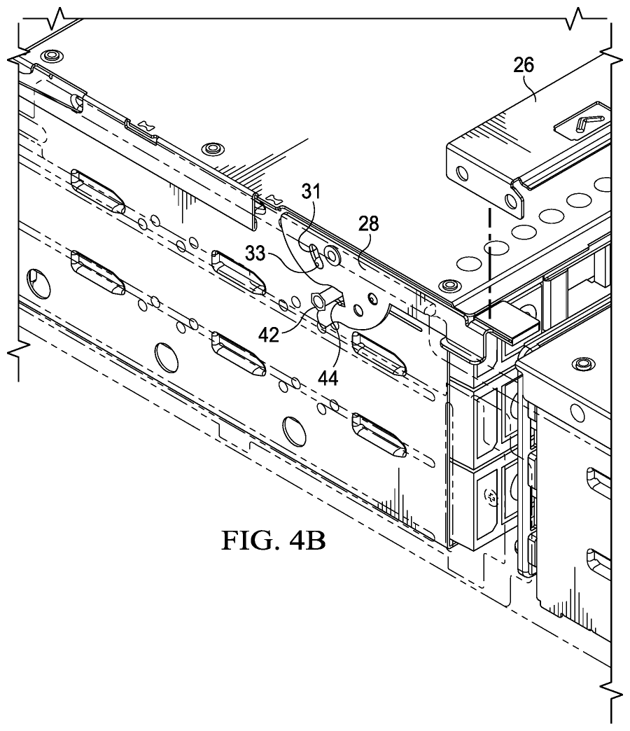

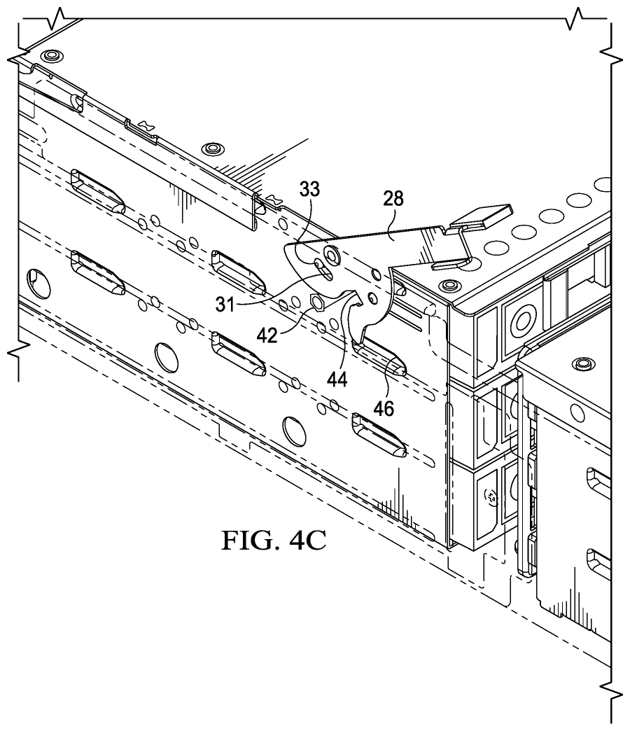

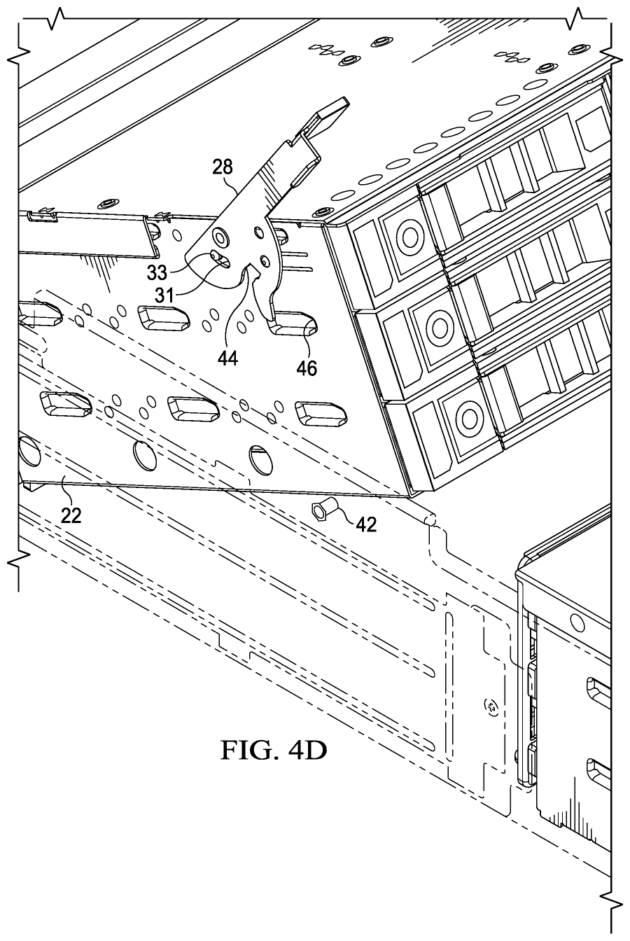

FIG. 2A depicts a detailed perspective view of a latch 28 coupled to a side of a storage drive bay 22 to rotate about a pivot 29. In the example depiction, latch 28 is rotated to a raised position at which an upward force applied to latch 28 is translated to storage drive bay 22 to cause upward rotation and thereby expose storage drives 24. A guide 31 is formed in latch 28 and engages with a pin 33 that extends out of storage drive bay 22 to define a rotational arc of latch 28 relative to storage drive bay 22. The end of latch 28 has an elastomeric over mold 30 that provides an end user with a firm grasp for applying force to move the latch and the storage drive bay. An extension member 32 extends at a bottom side of latch 28 to hold storage drive bay 22 in a closed position as described below in greater depth with respect to FIG. 4A. In the depicted example, storage drive bay 22 may be lowered from the raised position by pressing down on latch 28, which causes latch 28 to rotate down until the pin reaches a motion travel limit at alignment of latch 28 with an upper surface of storage drive bay 22 or just below the upper surface. Additional force then applied to latch 28 translates to a downward rotation of storage drive bay 22 until latch 28 enters the gap defined by housing placement of the front storage drive bay. Cover 26 is then coupled over the gap to capture latch 28 and hold storage drive bay 22 in place.

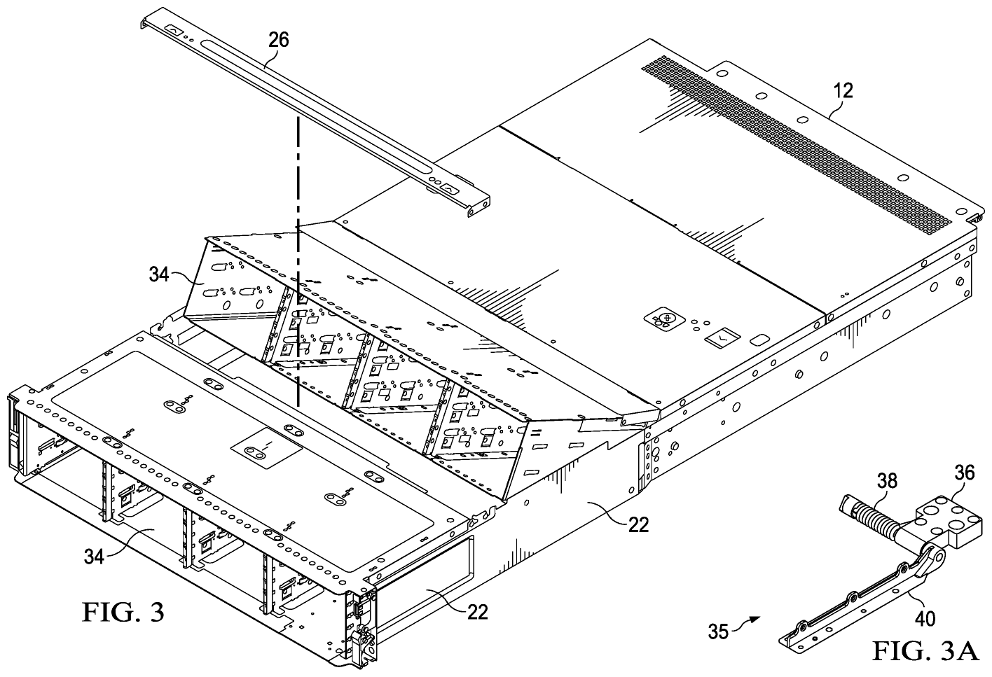

Referring now to FIGS. 3 and 3A, the server housing 12 is depicted with the middle-placed storage drive bay 22 held in a raised position by a hinge 35 having a counterbalance spring 38. FIG. 3A depicts hinge 35, which couples at the rear side of storage drive bay 22 with an arm 40 coupled to storage drive bay 22 and an asymmetric torque element and counterbalance spring 38 coupled to housing 12 to manage rotational force associated with movement of storage drive bay 22. For instance, when storage drives fill storage drive bay 22 to add weight, counterbalance spring 38 provides an opposing torque that biases storage drive bay 22 towards a raised position and asymmetric torque element 36 resists downward rotation. Various hinge mechanisms may be used to aid in opening storage drive bay 22 when weighted down by storage drives and also manage forces applied to close storage bay drive 22 to a planar position. The example embodiment has four sub-bays 34 in each storage drive bay 22 that each accept three vertically stacked storage devices. Alternative embodiments having fewer or more stacked storage devices may be used based upon the type of universal server rack that accepts housing 12. In the example embodiment, cover 26 fits over the gap defined between the storage drive bays.

Referring now to FIGS. 4A, 4B, 4C and 4D a side perspective detail view depicts operation of latch 28 to manage raising of storage bay drive 22 to access storage devices. FIG. 4A depicts storage drive bay 22 in a closed position with a planar orientation relative to the housing, such as to have a height that will fit into a server rack. Latch 28 has a closed position substantially aligned with the upper side of storage drive bay 22 and having its end under cover 26 located in the gap between the front of the middle-placed storage drive bay and rear of the front placed storage drive bay. Pin 33 inserts in guide 31 of latch 28 to provide for rotation of latch 28 relative to storage drive bay 22 if an upward force is applied to the latch 28. A locking pin 42 coupled to housing 12 engages with an extension member 44 of latch 28 to hold the latch in place relative to housing 12 when in the closed position. For example, a slight oversize of locking pin 42 provides a resistance to rotating latch 28 upwards and the insertion of locking pin 42 into extension member 44 stops vertical lifting of storage drive bay 22 until latch 28 rotates upwards. FIG. 4B depicts removal of cover 26 to expose latch 28 within the gap in front of storage drive bay 22. The position of the end of latch 28 in the gap area provides room for an end user finger to reach the end of latch 28 and initiate raising of latch 28. By having latch 28 extend across the full length of the gap, the increased length of latch 28 provides a greater moment for transfer of rotational force by lifting of the latch relative to the housing. From the depicted closed position, a relatively small lifting force applied to latch 28 raises latch 28 without raising storage drive bay 22 to a position at which guide 31 and pin 33 will translate lifting force applied to latch 28 to lift storage drive bay 22.

FIG. 4C depicts latch 28 lifted out of the gap to a raised position at which guide 31 stops rotation of latch 28 relative to storage drive bay 22 by engagement with pin 33. As pin 33 reaches a limit within guide 31 due to rotation of latch 28, force applied to latch 28 translates via pin 33 to storage drive bay 22 to lift the storage drive bay upwards and out of the housing to the open position depicted by FIG. 4D. In an alternative embodiment, extension member 44 may rotate against a stopping member 46 extending out of storage drive bay 22 to stop rotation of latch 28 relative to storage drive bay 22 and translate lifting force applied to the latch to lift the storage drive bay. Once latch 28 and storage drive bay 22 have reached a fully raised position, pressing down on latch 28 first rotates latch 28 to a level even with the upper surface of storage drive bay 22 and then, as guide 31 blocks further rotation due to pin 33, translates force applied down on latch 28 to rotate storage drive bay 22 downwards and into a stored position of chassis 12.

Although the present invention has been described in detail, it should be understood that various changes, substitutions and alterations can be made hereto without departing from the spirit and scope of the invention as defined by the appended claims.

1. An information handling system comprising:
a housing;
a processor disposed in the housing and operable to execute instructions to process information;
a memory disposed in the housing and interfaced with the processor, the memory operable to store the instructions and information;
a network interface card disposed in the housing and interfaced with the processor, the network interface card operable to communicate the information with a network;
first and second storage drive bays disposed in the housing, each storage drive bay configured to accept plural storage devices, the second storage drive bay rotationally coupled to the housing to rotate between a raised position and a closed position; and
a latch rotationally coupled at a side upper surface of the second storage bay, the latch having a stored position planar with the upper surface of the second storage bay drive and rotating relative to the second storage drive bay to a raised position about a single axis, the latch at the raised position having a pin of the second storage drive bay extending into a guide of the latch to define a range of rotation having a fixed position relative to the second storage drive bay when the latch rotates to a fully raised position, the latch in the fully raised position stopping rotation in response to a raising force, the raising force translated to raise the second storage drive bay to rotate the second storage drive bay to the raised position.

2. The information handling system of claim 1 further comprising:
a cover coupled to the housing between the first and second storage drive bays over a gap defined between the first and second storage drive bays; and
wherein the cover couples over the latch in the stored planar position and removes from the housing to release the latch for rotation to the raised position.

3. The information handling system of claim 2 wherein:
the first storage drive bay couples in a front side of the housing to expose storage drives disposed in the first storage bay at a front face of the housing;
the second storage drive bay couples in a middle position of the housing to face storage drives disposed in the second storage bay at a rear side of the first storage drive bay separated by the gap.

4. (canceled)

5. The information handling system of claim 2 further comprising first and second of latch coupled to opposing sides of the storage drive bay.

6. The information handling system of claim 2 further comprising:
a first member extending from the latch; and
a second member extending from the second storage drive bay, the second member restricting rotation of the latch by engagement with the first member.

7. The information handling system of claim 2 further comprising plural storage devices disposed in each of the first and second storage drive bays.

8. The information handling system of claim 2 further comprising a hinge rotationally coupling the second storage drive bay to the housing, the hinge having a counterbalance spring to bias the storage drive bay to a raised position and an asymmetric torque element to resist rotation of the second storage drive bay from the raised position.

9. The information handling system of claim 2 wherein the latch in the stored planar position extends across the gap.

10. A method for managing plural storage drive bays, the method comprising:
coupling a first storage drive bay at a front of a housing in a fixed orientation;
coupling a second storage drive bay at a middle of the housing at a rear side of the first storage drive bay with a gap between the first and second storage drive bays;
coupling a latch to the second storage drive bay, the latch extending into the gap, the latch rotating about a single axis;
coupling a pin from the second storage drive bay through a guide of the latch, the guide engagement with the pin defining a range of rotation of the latch;
rotating the latch relative to the second storage drive bay to a predetermined raised position out of the gap, the latch fully raised in the range of rotation so the pin works against an end of the guide; and
rotating the second storage drive bay to a raised position above the housing by lifting on the latch with the latch in a fixed raised position relative to the second storage drive bay, a rotating force applied to the latch translated to a raising force by the pin working against the end of the guide.

11. (canceled)

12. The method of claim 10 further comprising:
coupling a cover to the housing over the gap and over the latch when the latch extends into the gap; and
removing the cover to expose the latch.

13. The method of claim 10 further comprising:
coupling a first of the latch to a first side of the second storage drive bay;
coupling a second of the latch to a second side of the second storage drive bay opposite the first side; and
raising the second storage drive baby by lifting on both the first and second latches.

14. The method of claim 10 further comprising:
disposing plural storage devices in the first storage drive bay and accessible from the housing front; and
disposing plural storage devices in the second storage drive bay and accessible when the second storage drive bay is in the raised position.

15. The method of claim 10 further comprising extending the latch across the full size of the gap.

16. The method of claim 15 further comprising:
extending a first member from the latch; and
extending a second member from the second storage drive bay to engage the first member when the latch rotates to the predetermined raised position out of the gap.

17. A storage system comprising:
a storage drive bay having a front side configured to accept plural storage drives and a rear side rotationally coupled by a hinge;
a first latch rotationally coupled to a first side of the storage drive bay extending beyond the front side, the first latch rotating about a single axis relative to the storage drive bay from a stored position substantially level with a top side of the storage drive bay to a predetermined raised position over the top side, the latch at the predetermined raised position translating upward force to upward rotation of the storage drive bay;
a pin extending from the storage drive bay; and
a guide formed in the first latch and aligned to engage the pin, the guide defining rotation of the first latch from the stored position to the raised position and defining the predetermined raised position at which the first latch translates upward force to upward rotation, the translation of rotational force applied to the latch to a raising force to raise the rear side storage drive bay due to the pin working against an end of the guide.

18. The storage system of claim 17 further comprising a second latch rotationally coupled to a second side of the storage drive bay extending beyond the front side, the second latch rotating relative to the storage drive bay from a stored position substantially level with the top side of the storage drive bay to a predetermined raised position over the top side, the latch at the predetermined raised position translating upward force to upward rotation of the storage drive bay.

19. (canceled)

20. The storage system of claim 18 further comprising plural storage devices disposed in the storage drive bay.
